(19) United States
(12) Patent Application Publication
(10) Pub. No.: US 2008/0000511 A1
(43) Pub. Date: Jan. 3, 2008

(54) Thermoelectric conversion device and manufacture method of the same

(75) Inventors: Isao Kuroyanagi, Anjo-city (JP); Akio Matsuoka, Takahama-city (JP); Keizou Nimura, Nagoya-city (JP); Shin Nishiya, Okazaki-city (JP); Hiroyoshi Sugawara, Anjo-city (JP); Yuji Ito, Okazaki-city (JP); Yasuhiko Niimi, Handa-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/823,314

(22) Filed: Jun. 27, 2007

(30) Foreign Application Priority Data
Jun. 28, 2006 (JP) 2006-178307
Jun. 30, 2006 (JP) 2006-181101
Jan. 30, 2007 (JP) 2007-019951

(51) Int. Cl. H01L 35/32; H01L 35/34

(52) U.S. Cl. 136/201; 136/224

(57) ABSTRACT

A thermoelectric conversion device and a manufacture method for the thermoelectric conversion device are provided. The manufacture method includes a joining process for respectively joining heat exchanging members to thermoelectric-element pairs of an thermoelectric element module, an immersion process for immersing the thermoelectric element module and the heat exchanging members in an immersion sink where an melted insulating material is provided, and a baking process for baking an assembly of the thermoelectric element module and the heat exchanging members where the insulating material has been applied in the immersion process so that an insulating film is formed. Thus, an electrical insulation can be provided while a heat-exchanging capacity and an air-blowing capacity are maintained.

### CROSS REFERENCE TO RELATED APPLICATION

This application is based on a Japanese, Patent Application No. 2006-178307 filed on Jun. 28, 2006, a Japanese Patent Application No. 2006-181101 filed on Jun. 30, 2006 and a Japanese Patent Application No. 2007-19951 filed on Jan. 30, 2007, the disclosures of which are incorporated herein by reference.

### FIELD OF THE INVENTION

The present invention relates to a thermoelectric conversion device and a manufacture method of the same.

### BACKGROUND OF THE INVENTION

Generally, with reference to JP-2006-114840A, a thermoelectric, conversion device is provided with a thermoelectric element substrate and multiple heat exchanging members. Multiple thermoelectric-element pairs, each of which includes a P-type thermoelectric element and a N-type thermoelectric element, are arrayed at the thermoelectric element substrate. All of the thermoelectric elements are electrically connected with each other. The heat exchanging members are respectively provided for the thermoelectric-element pairs, to heat-exchange with the thermoelectric elements.

That is, in this case, the facade side and back side of the thermoelectric element substrate are respectively partitioned into a heat absorbing side and a heat radiating side, each of which is provided thereat with the multiple heat exchanging members. Thus, the heat resistances of the heat exchanging member and the thermoelectric element are decreased so that the thermoelectric conversion efficiency is improved, and the manufacture labor is reduced.

However, in this case, migration will be caused at the thermoelectric element and the joining portion between the thermoelectric element and the heat exchanging member, due to condensation water generated at the heat exchanging member of the heat absorbing side.

Moreover, all of the thermoelectric elements are electrically connected in series, through the heat exchanging members of the heat-absorbing side and those of the heat-radiating side. Thus, voltage is applied to the thermoelectric elements and the heat exchanging members when being provided with power supply, so that the parts which are adjacent to each other are constructed to be insulated from each other.

The insulating means is not described in JP-2006-114840A in detail. Generally, insulating coating or forming an insulating film by vapor deposition can be used to provide the electrically insulation. However, in the insulating coating or the vapor deposition, an insulating material is sprayed from the outer side of the thermoelectric element substrate. Thus, the insulating film at the outer side may be thick and that at the inner side may be thin. That is, variations in the thickness will occur.

Therefore, the minimum film thickness for the sake of the electrical insulation is to be set according to the film thickness of the inner side. Thus, the film thickness of the outer side will become thick to exceed a necessary degree. Therefore, the heat exchanging capacity will be deteriorated due to the increase of the heat resistance because of the thick film. Moreover, there will occur film stretching or the like at the narrow gap, so that the air-blowing resistance of an air blowing passage of an air blowing system will increase and the air-blowing capacity of the air blowing system will be deteriorated.

Furthermore, the variation in the film thickness easily occurs in the direction of the passage width of the air blowing passage. Therefore, a variation in the wind velocity and that in the temperature are caused, so that the heat-exchanging capacity is deteriorated.

Moreover, in this case, because the thermoelectric element substrate of the above described type is used for a small-sized cooling device or heating device, the multiple construction components such as the thermoelectric elements and the heat exchanging members which are minute are arrayed at the multiple rows with respect to the flowing direction of a heat transfer media. Thus, in this case, it is difficult to form the insulating film at the thermoelectric elements and the heat exchanging members which are arranged at the row of the inner side.

### SUMMARY OF THE INVENTION

In view of the above-described disadvantage, it is an object of the present invention to provide a thermoelectric conversion device where electrical insulation is provided while a heat-exchanging capacity and an air-blowing capacity are maintained, and a manufacture method of the same.

According to a first aspect of the present invention, a thermoelectric conversion device has a thermoelectric element module including a plurality of thermoelectric-element pairs each of which has a P-type thermoelectric element and a N-type thermoelectric element which are electrically connected with each other in series, and a plurality of heat exchanging members which are electrically joined with the thermoelectric elements. Heat is transferable between a heat transfer media and the thermoelectric elements through the heat exchanging members. The heat exchanging members are arranged at least three rows with respect to a flow direction of the heat transfer media. An insulating film is provided at a substantially whole surface of an assembly of the thermoelectric element module and the heat exchanging members, by electrodeposition coating.

Because the insulating film is formed by immersing the thermoelectric element module in the electrodeposition sink, the insulating film having an even thickness can be provided at the substantially whole surface of the assembly of the thermoelectric element module and the heat exchanging members. In this case, the thermoelectric elements and the heat exchanging members are arrayed at the multiple rows with respect to the flow direction of the heat transfer media. Thus, the insulating film can be evenly formed at the thermoelectric elements and the heat exchanging members which are arranged at the rows of the inner side.

Because the insulating film having the predetermined thickness can be formed, the deterioration of an air-blowing capacity of an air blowing system and the deterioration of a heat-exchanging capacity due to the thick film can be reduced.

Moreover, because the electrodeposition coating is a method for applying the insulating material by applying the voltage to the part where the insulating film is to be formed, the insulating film having the even thickness can be formed at the current-carrying part of the thermoelectric element substrate unit. Furthermore, because the film having a thickness larger than a necessary value is reduced, the film stretching can be restricted from occurring at a narrow gap.

Furthermore, because the insulating film is readily formed at the joining portion between the thermoelectric element and the heat exchanging member, migration can be restricted.

According to a second aspect of the present invention, a manufacture method is provided for a thermoelectric conversion device which includes a thermoelectric element module and a plurality of heat exchanging members. The thermoelectric element module includes a plurality of thermoelectric-element pairs each of which has a P-type thermoelectric element and a N-type thermoelectric element connected with each other in series. The manufacture method includes a joining process for respective joining the heat exchanging members to the thermoelectric-element pairs, an immersion process and a baking process. Heat is transferable between a heat transfer media and the thermoelectric elements through the heat exchanging members. The heat exchanging members are electrically connected with the thermoelectric elements and arranged at least three rows with respect to a flow direction of the heat transfer media. In the immersion process, an assembly of the thermoelectric element module and the heat exchanging members is immersed in an immersion sink in which an melted insulating material is provided to apply the insulating material to a substantially whole surface of the assembly by applying a predetermined voltage to the assembly. The immersion process is performed after the joining process. In the baking process, the assembly of the thermoelectric element module and the heat exchanging members where the insulating material has been applied in the immersion process is baked, so that an insulating film is formed.

Because the electrodeposition coating including the baking process and the immersion process which are performed after the joining process for joining the thermoelectric element pair with the heat exchanging member, the insulating film can be formed by immersing the thermoelectric element module in the electrodeposition sink. Therefore, the insulating film having an even thickness can be provided at the substantially whole surface of the assembly of the thermoelectric element module and the heat exchanging members.

In this case, for the thermoelectric element module where the thermoelectric elements and the heat exchanging members are arrayed at the multiple rows with respect to the flow direction of the heat transfer media, the insulating film can be evenly formed at the thermoelectric elements and the heat exchanging members which are arranged at the rows of the inner side. Thus, the deterioration of an air-blowing capacity of an air blowing system and the deterioration of a heat-exchanging capacity due to the thick film can be reduced.

Moreover, in the immersion process, the insulating material is applied by applying the predetermined voltage to the assembly of the thermoelectric element module and the heat exchanging members, so that the insulating film having the even thickness can be formed at the current-carrying part of the thermoelectric element module. Furthermore, because the film having a thickness larger than a necessary value is reduced, the film stretching can be restricted from occurring at a narrow gap.

Furthermore, because the insulating film is readily formed at the joining portion between the thermoelectric element and the heat exchanging member, migration can be restricted.

### BRIEF DESCRIPTION OF THE DRAWINGS

Other objects, features and advantages of the present invention will become more apparent from the following detailed description made with reference to the accompanying drawings, in which:

FIG. 1 is a schematic view showing an appearance of a thermoelectric conversion device before fixing members are mounted according to a first embodiment of the present disclosure;

FIG. 2 is a schematic sectional view taken along a line II-II in FIG. 1;

FIG. 3 is a schematic disassembled sectional view showing a main part of the thermoelectric conversion device according to the first embodiment;

FIG. 4 is a schematic view showing an arrangement of P-type thermoelectric elements and N-type thermoelectric elements of a thermoelectric element substrate unit when being viewed along the direction of arrow IV in FIG. 2;

FIG. 5 is a schematic sectional view taken along the line V-V in FIG. 2;

FIG. 6A is a partially sectional view showing an immersion process according to the first embodiment, and FIG. 6B is a partially sectional view showing a baking process according to the first embodiment;

FIG. 7A is a schematic view showing a heat exchanging member, FIG. 7B is a schematic view showing the heat exchanging member when being viewed in the direction VIIB in FIG. 7A, FIG. 7C is a schematic sectional view taken along the line VIIC-VIIC in FIG. 7A, FIG. 7D is an enlarged view showing the VIID part of FIG. 7C, and FIG. 7E is an enlarged view showing the VIIE part of FIG. 7D;

FIG. 8 is a graph showing a forming of an insulating film by electrodeposition coating according to the first embodiment and that according to a comparison example;

FIG. 9 is a schematic view showing a thermoelectric conversion device according to a second embodiment of the present disclosure;

FIG. 10 is a schematic sectional view taken along the line X-X in FIG. 9;

FIG. 11 is a schematic disassembled sectional view showing a main part of the thermoelectric conversion device according to the second embodiment;

FIG. 12 is a schematic view showing a thermoelectric conversion device according to a third embodiment of the present disclosure;

FIG. 13 is a schematic view showing an arrangement of P-type thermoelectric elements and N-type thermoelectric elements of a thermoelectric element substrate unit when being viewed along the direction of arrow XIII in FIG. 12;

FIG. 14 is a schematic disassembled sectional view showing a main part of the thermoelectric conversion device according to the third embodiment;

FIG. 15 is a schematic sectional view taken along the line XV-XV in FIG. 12;

FIG. 16 is an enlarged view showing the XVI part of FIG. 15;

FIG. 17 is a schematic view showing an electrodeposition coating method according to the third embodiment;

FIG. 18 is a schematic sectional view showing a main part of a thermoelectric conversion device according to a fourth embodiment of the present disclosure;

FIG. 19 is an enlarged view showing the XIX part of FIG. 18;

FIG. 20 is a schematic view showing a main part of a thermoelectric conversion device according to a fifth embodiment of the present disclosure; and

FIG. 21 is a schematic view showing a main part of a thermoelectric conversion device according to a sixth embodiment of the present disclosure.

### DETAILED DESCRIPTION OF THE EXAMPLED EMBODIMENTS

### First Embodiment

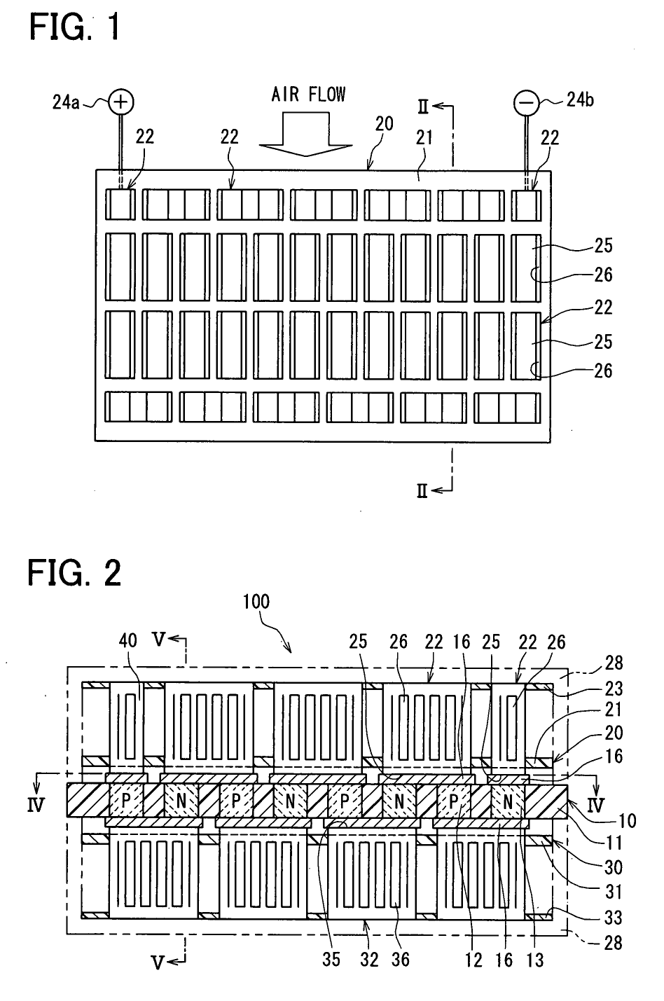

A thermoelectric conversion device 100 according to a first embodiment of the present invention will be described with reference to FIGS. 1-8. The thermoelectric conversion device 100 can be suitably used for a cooling device or a heating device. For example, the thermoelectric conversion device 100 can be suitably used in a seat air-conditioning device mounted at a vehicle. In this case, each of a sitting portion and a back portion of a seat of the vehicle can be provided with the thermoelectric conversion device 100, so that cool air cooled by the thermoelectric conversion device 100 can be blown outward from the surface of the seat. It is desirable for the thermoelectric conversion device 100 to be small-sized to be mounted in the vehicle seat where the mounting space is narrow.

As shown in FIGS. 1-5, the thermoelectric conversion device 100 is provided with a thermoelectric element substrate unit 10 (thermoelectric element module), a first fin board unit 20 of a heat-absorbing side, a second fin board unit 30 of a heat-radiating side, and two case members 28.

With reference to FIGS. 2-5, the thermoelectric element substrate unit 10 includes P-type thermoelectric elements 12, N-type thermoelectric elements 13, electrode members 16, and a insulating substrate 11 for holding the thermoelectric elements 12 and the thermoelectric elements 13. The thermoelectric element 12, the thermoelectric element 13, the electrode member 16 and the insulating substrate 11 are integrated with each other.

Specifically, the insulating substrate 11 can be made of a substantially plate-shaped insulating material (for example, glass epoxy, phenol resin, PPS resin, LCP resin or PET resin). The insulating substrate 11 is provided with multiple thermoelectric element groups which are arranged in a pattern of substantial lattice of uniform squares. Each of the thermoelectric element groups includes the one P-type thermoelectric element 12 and the one N-type thermoelectric element 13. That is, the P-type thermoelectric elements 12 and the N-type thermoelectric elements 13 are alternately arrayed at the insulating substrate 11. The end surface of the thermoelectric element 12 and the end surface (which is positioned at the same side as this end surface of thermoelectric element 12 with respect to thermoelectric element substrate unit 10) of the thermoelectric element 13 which are adjacent to each other are joined to the electrode member 16.

The thermoelectric elements 12 (being minute component, for example) can be constructed of a P-type semiconductor comprised of Bi—Te compound (bismuth telluride compound). The thermoelectric element 13 (being minute component, for example) can be constructed of a N-type semiconductor comprised of Bi—Te compound. The two end surfaces (for example, upper end surface and lower end surface) of each of the thermoelectric elements 12 and 13 protrude from the insulating substrate 11.

The electrode member 16 is constructed of a conductive metal such as copper and has a substantial plate shape. The thermoelectric element 12 and the thermoelectric element 13 which are adjacent to each other are connected with each other in series by the electrode member 16.

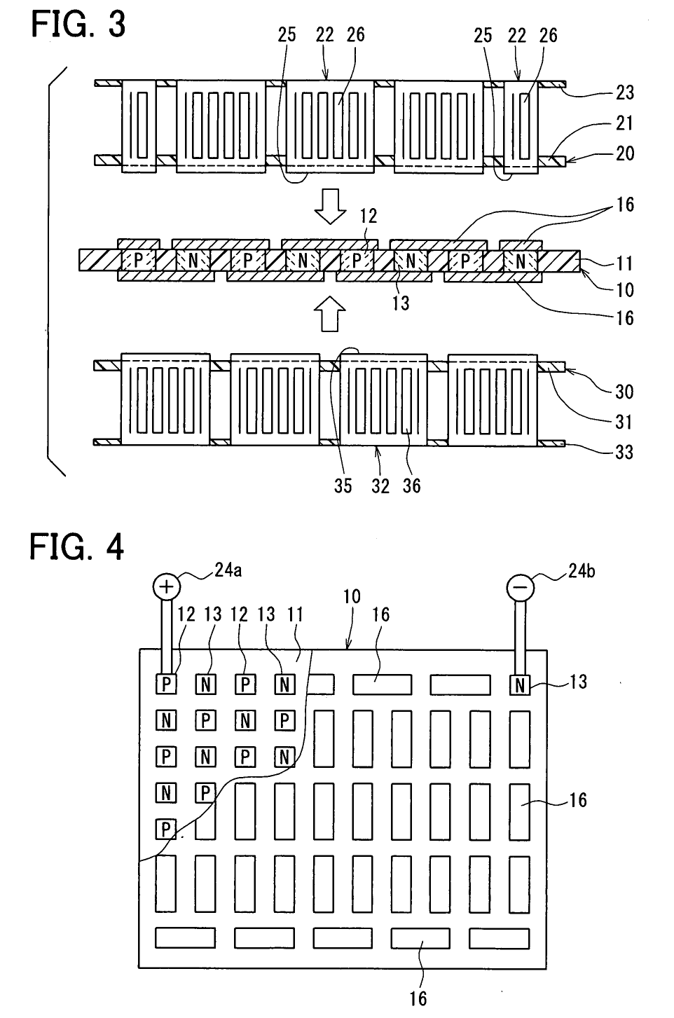

As shown in FIGS. 2 and 3, the electrode member 16 which is arranged at the one side (e.g., upper side) of the insulating substrate 11 is an electrode through which current flows from the thermoelectric element 13 to the thermoelectric element 12 (adjacent to this thermoelectric element 13). The electrode member 16 which is arranged at the other side (e.g., low side) of the insulating substrate 11 is an electrode through which current flows from the thermoelectric element 12 to the thermoelectric element 13 (adjacent to this thermoelectric element 12).

In this case, the electrode member 16 can be joined to the end surfaces of the thermoelectric element 12 and the thermoelectric element 13 by soldering or the like, by beforehand thinly applying paste solder or the like to the end surfaces by screen printing, for example.

The first fin board unit 20 includes a heat exchanging member 22 (for absorbing heat) and an insulating board 21 (first holding member) which are integrated with each other. The insulating board 21 (holding member) can be made of a substantially plate-shaped insulating material (for example, glass epoxy, phenol resin, PPS resin, LCP resin or PET resin). The second fin board unit 30 includes a heat exchanging member 32 (for radiating heat) and a third insulating board 31 (first holding member) which are integrated with each other. The third insulating board 31 (holding member) can be made of a substantially plate-shaped insulating material (for example, glass epoxy, phenol resin, PPS resin, LCP resin or PET resin).

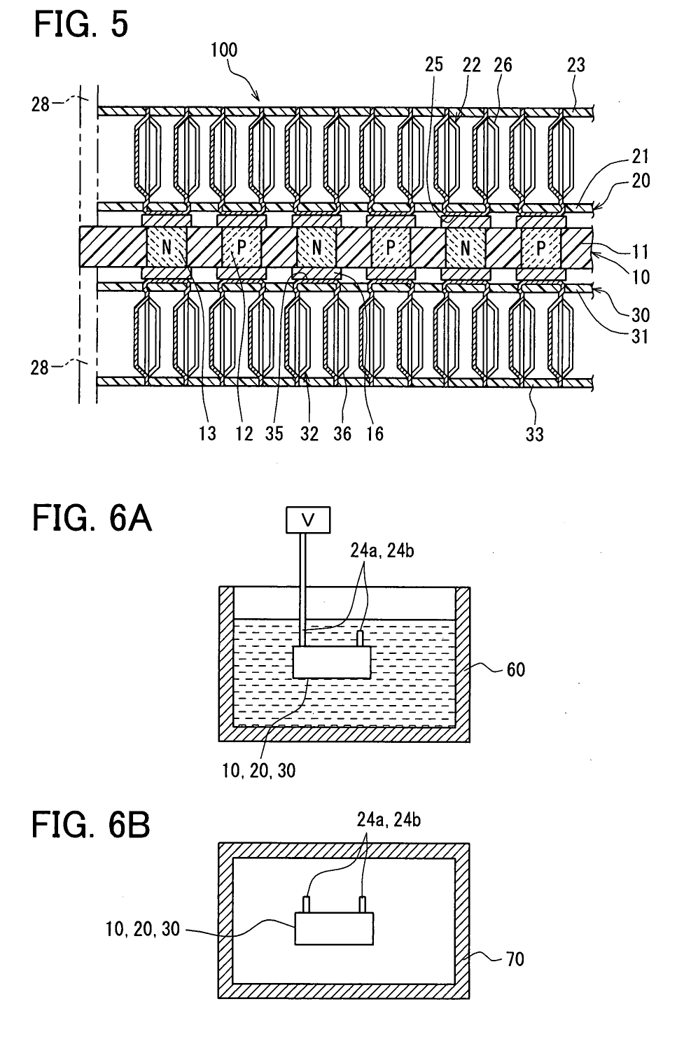

Each of the heat exchanging member 22 and the heat exchanging member 32 can be constructed of a thin plate material of a conductive metal such as copper or the like and have a substantial U-like shape. As shown in FIG. 5, the heat exchanging member 22 includes a heat-absorbing electrode portion 25 which is constructed of the bottom portion of the heat exchanging member 22 having the U-like shape, and a heat exchanging portion 26 which extends from the heat-absorbing electrode portion 25 and has a louver shape. The heat exchanging member 32 includes a heat-radiating electrode portion 35 which is constructed of the bottom portion of the heat exchanging member 32 having the U-like shape, and a heat exchanging portion 36 which extends from the heat-radiating electrode portion 35 and has a louver shape.

The heat exchanging portion 26 which is integrated with the heat-absorbing electrode portion 25 is a fin member for absorbing heat transferred through the heat-absorbing electrode portion 25, and can be formed by lancing or the like. The heat exchanging portion 36 which is integrated with the heat-radiating electrode portion 35 is a fin member for radiating heat transferred through the heat-radiating electrode portion 35, and can be formed by lancing or the like.

The heat-absorbing electrode portion 25 and the heat-radiating electrode portion 35 are respectively integrally fixed to the insulating board 21 and the third insulating board 31, in such a manner that the end surfaces of the heat-absorbing electrode portion 25 and the heat-radiating electrode portion 35 are joined to the electrode members 16.

The electrode portion 25 of the heat exchanging member 22 is constructed in such a manner that the end of the heat-absorbing electrode portion 25 slightly protrude from the surface of the insulating board 21, and the electrode portion 35 of the heat exchanging member 32 is constructed in such a manner that the end of the heat-radiating electrode portion 35 slightly protrude from the surface of the third insulating board 31.

That is, the electrode portion 25 (35) is constructed without protruding to the side of the thermoelectric element 12, 13 from the insulating board 21(31) when the end surface of the heat-absorbing electrode portion 25 (35) contacts the electrode member 16 arranged at the thermoelectric element substrate unit 10.

The heat exchanging members 22 are arranged at the insulating board 21 in the pattern of substantial lattice of uniform squares and spaced from each other at a predetermined distance, so that the heat-exchanging members 22 are insulated from each other. The heat exchanging members 32 are arranged at the third insulating board 31 in the pattern of substantial lattice of uniform squares and spaced from each other at a predetermined distance, so that the heat-exchanging members 32 are insulated from each other.

The heat-absorbing electrode portion 25 of the heat exchanging member 22 is arranged corresponding to the electrode member 16 of the upper side, and joined to the electrode member 16. The heat-radiating electrode portion 35 of the heat exchanging member 32 is arranged corresponding to the electrode member 16 of the lower side, and joined to the electrode member 16.

As shown in FIGS. 2 and 3, a fixing member 23 and a fixing member 33, each of which constructs a second holding member and is an insulating board, are respectively arranged at the two end sides (e.g., uppermost side and lowermost side) of the space defined in the case members 28, to respectively hold the ends (e.g., upper ends) of the heat-exchanging members 22 and the ends (e.g., lower ends) of the heat-exchanging members 32. Thus, the adjacent heat-exchanging members 22 (32) can be spaced from each other at the predetermined distance, and electrically insulated from each other.

Each of the fixing member 23 and the fixing member 33 can be made of a substantially plate-shaped insulating material (for example, glass epoxy, phenol resin, PPS resin, LCP resin or PET resin), and provided with multiple fixing holes (not shown) through which the ends of the heat exchanging members 22 (32) are inserted.

As shown in FIG. 1, connection terminals 24a and 24b as power source terminals are respectively connected with the thermoelectric element 12 and the thermoelectric element 13 which are respectively positioned at the two ends (e.g., left end and right end) of the insulating substrate 11. The connection terminal 24a can be further connected with the positive terminal of a direct current power source (not shown), the connection terminal 24b can be further connected with the negative terminal of the direct current power source.

Thus, the multiple electrode members 16 and the multiple heat-exchanging members 22 which are arranged at the upper side are electrically connected with first ends (e.g., upper ends) of the P-type thermoelectric elements 12 and first ends (e.g., upper ends) of the N-type thermoelectric elements 13. The multiple electrode members 16 and the multiple heat-exchanging members 32 which are arranged at the lower side are electrically connected with second ends (e.g., lower ends) of the P-type thermoelectric elements 12 and second ends (e.g., lower ends) of the N-type thermoelectric elements 13.

When a voltage is applied to the connection terminal 24a, direct current will flow in series from the thermoelectric element 12 of the left side in FIG. 2 to the thermoelectric element 13 through the electrode member 16 arranged at the lower side, and then flow in series from this thermoelectric element 13 to the thermoelectric element 12 through the electrode member 16 arranged at the upper side.

In this case, the electrode member 16 which is arranged at the lower side of the PN joining portion has a high temperature state due to a Peltier effect, and the electrode member 16 which is arranged at the upper side of the NP joining portion has a low temperature state. That is, the heat exchanging portion 26 arranged at the upper side construct a heat exchanging portion to absorb heat form heat transfer media (contacting heat exchanging portion 26) which is to be cooled. The heat exchanging portion 36 arranged at the lower side construct a heat exchanging portion to radiate heat to heat transfer media (contacting heat exchanging portion 36) for cooling.

As shown FIG. 2, the case members 28 can respectively construct air passages (which are partitioned from each other by thermoelectric element substrate unit 10) at the two sides (of up-down direction, for example) of the thermoelectric element substrate unit 10. The heat transfer media such as air flows through the air passages to heat-exchange with the heat exchanging portion 26 and the heat exchanging portion 36. Therefore, air can be cooled at the heat exchanging portion 26 of the upper side, and heated at the heat exchanging portion 36 of the lower side, with the thermoelectric element substrate unit 10 as the partition wall.

In this embodiment, the positive terminal of the direct current power source is connected with the connection terminal 24a and the negative terminal thereof is connected with the connection terminal 24b, so that the direct current is inputted to the connection terminal 24a. Alternatively, the positive terminal of the direct current power source can be connected with the connection terminal 24b and the negative terminal thereof can be connected with the connection terminal 24a, so that the direct current is inputted to the connection terminal 24b. In this case, the heat exchanging member 22 of the upper side constructs the heat exchanging portion for heat-radiating, and the heat exchanging member 32 of the lower side constructs the heat exchanging portion for heat-absorbing.

According to this embodiment, an insulating film is provided at a substantially whole surface of an assembly of the thermoelectric element module 10 and the heat exchanging members 22, 32.

Next, the manufacture method of the thermoelectric conversion device 100 will be described.

As shown in FIGS. 3 and 4, the multiple P-type thermoelectric elements 12 and the multiple N-type thermoelectric elements 13 are alternately arranged at holes arranged at the insulating substrate 11 in the pattern of substantial lattice of uniform squares, to be constructed integrally with the insulating substrate 11. Thus, the two end surfaces of each of the thermoelectric element 12 and the thermoelectric element 13 which are adjacent to each other and arranged at the insulating substrate 11 are respectively joined to the electrode members 16 by soldering or the like, so that the thermoelectric element 12 and the electrode member 16 are connected with in series.

Thus, the thermoelectric element 12, the thermoelectric element 13 and the electrode member 16 are integrated with the insulating substrate 11, so that the thermoelectric element substrate unit 10 is constructed. The NP joining portion is constructed of the electrode member 16 arranged at the upper side, and the PN joining portion is constructed of the electrode member 16 arranged at the lower side. The thermoelectric element 12 and the thermoelectric element 13 are electrically connected with each other in series.

Alternatively, the thermoelectric element 12, the thermoelectric element 13 and the electrode member 16 can be also assembled by using a mounter which is a manufacture device for attaching semiconductor or electronic components to a control substrate. In this case, when the size of the thermoelectric element 12, 13 is larger than 1.5 mm×1.5 mm, the thermoelectric element 12, 13 can be readily picked up to be assembled with an improved productivity.

Then, the heat-absorbing electrode portion 25 is inserted to the engagement holes arranged at the insulating board 21, and the heat-exchanging members 22 are picked up and arrayed at the insulating board 21. Thus, the first fin board unit 20 is constructed. The heat-radiating electrode portion 35 is inserted to the engagement holes arranged at the third insulating board 31, and the heat-exchanging members 32 are picked up and arrayed at the third insulating board 31. Thus, the second fin board unit 30 is constructed.

Thereafter, a joining process will be performed. In this case, the thermoelectric element substrate unit 10 is sandwiched between the first fin board unit 20 and the second fin board unit 30 to be assembled, and the electrode portions 25 and 35 are respectively contacted with the electrode members 16 to be joined to each other by soldering or the like together.

Alternatively, in the joining process, the first fin board unit 20 can be also superimposed at the thermoelectric element substrate unit 10 so that the electrode member 16 and the heat-absorbing electrode portion 25 contact each other and are joined to each other only at the single-sided surface. Thereafter, the thermoelectric element substrate unit 10 is reversed to be superimposed at the second fin board unit 30, and then the electrode member 16 and the heat-radiating electrode portion 35 are joined to each other.

Then, in a fixing-member assembling process, the ends portions (which are at opposite side of heat exchanging member 22 to heat-absorbing electrode portion 25) of the heat-exchanging members 22 are arranged in the fixing holes of the fixing member 23 to be fixed. The ends portions (which are at opposite side of heat exchanging member 32 to heat-radiating electrode portion 35) of the heat-exchanging members 32 are arranged in the fixing holes of the fixing member 33 to be fixed. Thus, the heat-exchanging members 22 (32) which are adjacent to each other can be spaced from each other at the predetermined distance, to be electrically insulated.

Next, an electrodeposition coating is performed to assemble the first fin board unit 20, the second fin board unit 30, the fixing member 23 and the fixing member 33 to the thermoelectric element substrate unit 10. The electrodeposition coating includes an immersion process shown in FIG. 6A, and a baking process shown in FIG. 6B.

In the immersion process, with reference to FIG. 6A, the thermoelectric element substrate unit 10 to which the heat exchanging member 22 of the first fin board unit 20 and the first fin board unit 20 of the heat exchanging member 32 are attached is immersed in an electrodeposition sink 60 where an insulating material, for example, an electrolytic type electrodeposition paint is melted, so that the insulating material is applied to the substantially whole surface of the assembly. In this case, an applying device is electrically connected with the connection terminal 24a and the connection terminal 24b of the first fin board unit 20, so that a predetermined voltage is applied. Thus, a predetermined immersion period of time can be provided.

In the baking process, with reference to FIG. 6B, the insulating material applied to (at the immersion process) the outer surface of the assembly including the thermoelectric element substrate unit 10 and the heat exchanging members 22 and 32 are assembled is baked, so that the insulating film is produced. In this case, the thermoelectric element substrate unit 10 having been provided with the immersion process is arranged in a constant temperature bath 70 where a predetermined baking temperature is set, so that the insulating material is baked.

Thus is, the liquid insulating material applied to the surface of the thermoelectric element substrate unit 10 where the heat exchanging member 22 and the fixing member 23 are attached is hardened in an atmosphere having a high temperature. Thus, the insulating film having a predetermined thickness is produced. In this case, the baking condition such as a baking temperature, a baking period of time and baking times and the like can be changed so that the hardening period of time, the film thickness, and the film density of the insulating film and the like can be adjusted.

For example, the baking can be performed multiple times (e.g., baking process can sequentially include half baking, intermediate baking and finishing baking). In this case, the baking temperature and the baking period of time can be correspondingly set.

According to the above-described electrodeposition coating, the insulating material can be applied to the substantially whole surfaces of the thermoelectric element substrate unit 10, the heat exchanging member 22 and the heat exchanging member 32. In this case, the voltage is applied to the connection terminal 24a and the connection terminal 24b. Thus, the predetermined voltage can be applied to the current-carrying part of the thermoelectric element substrate unit 10, that is, all of the thermoelectric elements 12 and the thermoelectric elements 13 and the electrode members 16 and the heat-exchanging members 22 and 32.

Thus, the insulating material can be applied to the part where the voltage is applied. Moreover, the insulating film can be evenly applied because the thickness of the insulating film is determined in response to the applied voltage. In this case, the insulating material is not applied to the part where the voltage is not applied. That is, the insulating film is not formed at the insulating substrate 11, the insulating board 21, the third insulating board 31 and the like. That is, film stretching can be restricted as compared with a spraying method where the insulating material is sprayed from the outer side.

In this embodiment, the electrolytic active type electrodeposition paint or the like can be used as the insulating material melted in the electrodeposition sink. The electrolytic active type electrodeposition paint can be made of a material where the ratio of an edge-cover resin material in a base resin material made of a denatured epoxy is increased so that the insulating film can be evenly formed. The edge-cover resin material is a resin material having a high viscosity when being melted in the insulating material in the electrodeposition sink.

In this case, both of the base resin material and the edge-cover resin material are insulating material. The viscosity of the base resin material can be increased when the base resin material and the edge-cover resin material are melted in the electrodeposition sink. That is, because the ratio of the edge-cover resin material in the base resin material is increased, the liquid drooping can be restricted when the electrolytic active type electrodeposition paint is applied. That is, the liquid drooping (due to surface tension) at the electrodeposition paint applied to the edge surface can be restricted, when the product is taken out from the electrodeposition sink.

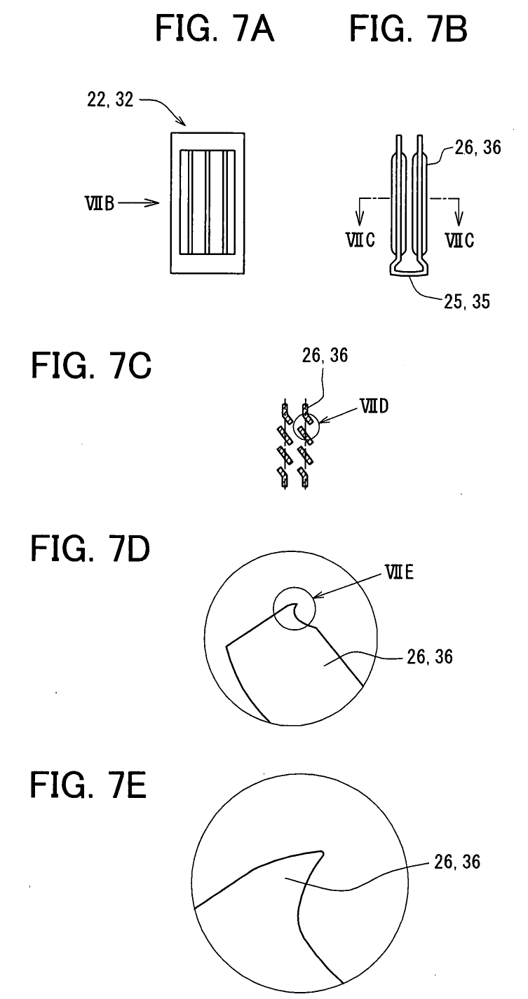

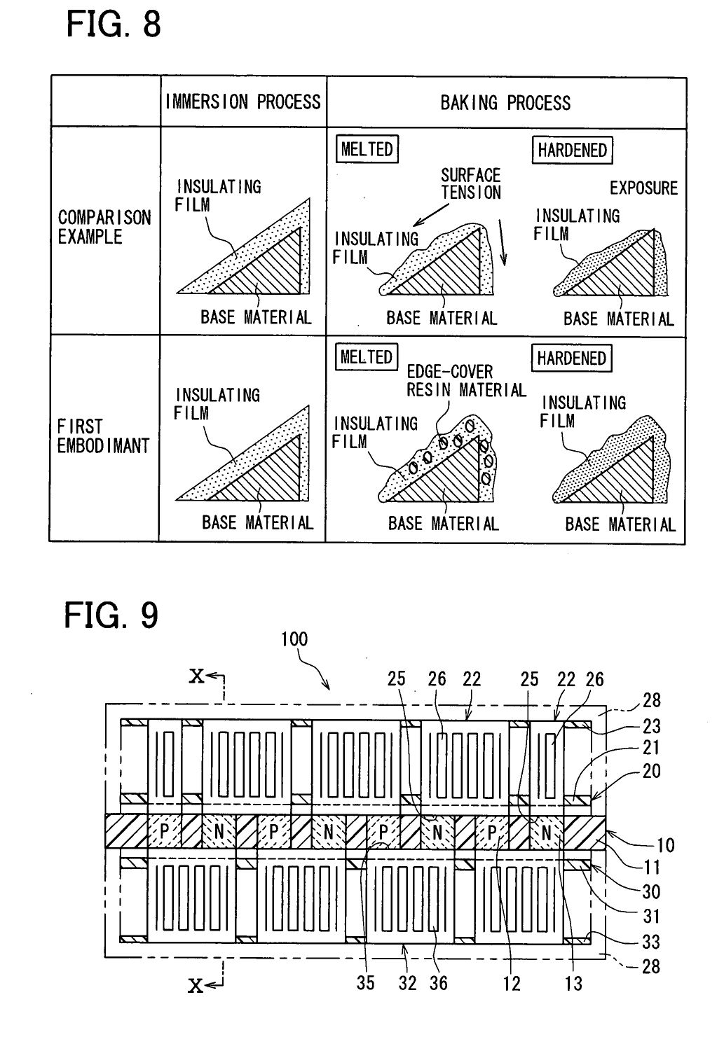

In this embodiment, the thermoelectric element 12, the thermoelectric element 13, the electrode member 16, the heat exchanging member 22 and the heat exchanging member 32 can be minute components and arranged at multiple rows with respect to the flowing direction of the heat transfer media. In this case, the insulating film can be substantially formed by using the electrolytic active type electrodeposition paint. That will be described with reference to FIGS. 7A-8.

FIGS. 7A and 7B show the heat exchanging member 22 and the fixing member 23, where the heat exchanging portion 26 and the heat exchanging portion 36 (which have louver shape) respectively extend outward from the heat-absorbing electrode portion 25 and the heat-radiating electrode portion 35.

FIG. 7C is a sectional view taken along a line VIIC-VIIC in FIG. 7B to show the shape of the heat exchanging portion 26 and the heat exchanging portion 36 having the lover shape. FIG. 7D is an enlarged view of the VIID part of FIG. 7C when being viewed by a microscope to show the tip portions of the heat exchanging portion 26, 36 where the edge surfaces protruding outward are formed.

FIG. 7E is an enlarged view of the VIIE part of FIG. 7D when being viewed by a microscope to show the tip portions of the heat exchanging portion 26, 36 where the edge surfaces having an acute angle shape are formed. Moreover, in this case, each of the heat exchanging portion 26 and the heat exchanging portion 36 is provided with multiple portions each of which has the edge surface with the acute angle shape, for example.

FIG. 8 shows the insulating material of this embodiment and an insulating material according to a comparison example where a general base resin material is used.

According to the comparison example, as shown in FIG. 8, the insulating film is evenly formed around the base material in the immersion process. However, in the melted state of the baking process, there will occur liquid drooping (due to surface tension) at the applied insulating material. That is, at the edge surface, the insulating material will become thin due to the liquid drooping. Thus, when the baking is provided at this state, the edge surface will be exposed without being covered by the insulating film.

According to this embodiment of the present invention, in the melted state of the baking process, the liquid drooping can be restricted because of the increased viscosity of the edge-cover resin material, so that the insulating film at the edge surface can be restricted from becoming thin. When the baking process is performed at this state, the insulating film (including that at the edge surface) having the predetermined thickness can be formed. Thus, the insulating film can be substantially evenly formed. Therefore, the insulating film having the predetermined thickness can be provided.

Accordingly, the adjacent parts of the thermoelectric elements 12, 13, the electrode member 16, the heat exchanging member 22 and the heat exchanging member 32 can be electrically insulated from each other. Moreover, the gaps arranged between the adjacent parts of the thermoelectric elements 12, 13, the electrode member 16, the heat exchanging member 22 and the heat exchanging member 32 can be reduced.

Furthermore, in this embodiment, the multiple heat-exchanging members 22 (32) are arranged at the multiple rows in the flowing direction of the heat transfer media. When the immersion process and the baking process are performed, the insulating film having the even thickness can be formed at the interior of the thermoelectric element 12, the thermoelectric element 13, the electrode member 16, the heat exchanging member 22 and the heat exchanging member 32 which are arranged at the inner side of the thermoelectric element substrate unit 10. Particularly, the improvement of the insulating film forming is apparent in the case where the thermoelectric elements 12 and 13, the electrode members 16, the multiple heat-exchanging members 22 and the heat exchanging members 32 are arranged at three rows or more with respect to the flow direction of the heat transfer media.

In the immersion process, the immersion condition including the applying voltage, the immersion period of time, the immersion times and the like can be changed to adjust the thickness, the density and the like of the insulating film. For example, in the immersion process, the product can be immersed several times, so that the insulating material can be applied to the part where the insulating material has not been applied last time. Moreover, the thickness of the insulating film can be adjusted by changing the applying voltage and the immersion time.

After the electrodeposition coating is finished, the assembling is performed so that the upper surface of the insulating board 21 and the side surface the case member 28 of the upper side surround therein a space defining the one air passage. Similarly, the lower surface of the third insulating board 31 and the side surface of the case member 28 of the lower side surround therein a space defining the other air passage.

Thus, the heat exchanging portion for heat-absorbing and the heat exchanging portion for heat-radiating are respectively formed at the upper side and the lower side of the thermoelectric element substrate unit 10. In this case, air can be provided to flow through the heat exchanging portions, so that cool air and warm air can be obtained.

According to this embodiment, the film stretching can be restricted from occurring at the gap between the heat exchanging member 22 and the heat exchanging member 32. Moreover, the insulating film can be evenly formed at the heat exchanging member 22 and the heat exchanging member 32 by electrodeposition coating, so that the wind velocity distribution and the temperature distribution of the air passage of the heat exchanging portion can become even. Furthermore, the air-blowing performance of an air blowing system of the seat air-conditioning device or the like can be improved. In addition to the seat air-conditioning device, the thermoelectric conversion device 100 can be also used to cool a heat-generating component such as a semiconductor or electric component and heat in a heating device.

According to this embodiment, the insulating film is formed at the thermoelectric element substrate unit 10 (where heat exchanging members 22 and 32 are attached) by the electrodeposition coating having the immersion process and the baking process. In this case, the thermoelectric element substrate unit 10 can be immersed in the electrodeposition sink, so that the insulating film is formed. Therefore, the thermoelectric element substrate unit 10 to which the heat exchanging member 22 and the heat exchanging member 32 are attached can be provided with the insulating film having the substantially even thickness.

Particularly, the thermoelectric element substrate unit 10 is provided with the multiple thermoelectric elements 12 (13) which are arrayed at the multiple rows in the flow direction of the heat transfer media. Furthermore, the thermoelectric element substrate unit 10 is provided with the multiple heat-exchanging members 22 (32) which are arrayed at the multiple rows in the flow direction of the heat transfer media. In this case, the insulating film can be evenly formed at the interior of the thermoelectric element 12, the thermoelectric element 13, the electrode member 16, the heat exchanging member 22 and the heat exchanging member 32 which are arranged at the rows of the inner side. Thus, the insulating film having the predetermined thickness can be formed, and the deterioration of the air-blowing capacity of the air blowing system and the deterioration of the heat-exchanging capacity due to the thick film can be reduced.

Moreover, because the electrodeposition coating is a method for applying the insulating material by applying the voltage to the part where the insulating film is to be formed, the insulating film having the even thickness can be formed at the current-carrying part (that is, thermoelectric element 12, thermoelectric element 13, electrode member 16, heat exchanging member 22 and heat exchanging member 32) of the thermoelectric element substrate unit 10.

Furthermore, because the film having the thickness larger than the necessary value is restricted from occurring, the film stretching at the narrow gap can be restricted. Because the insulating film is not formed at the part (that is, insulating substrate 11, insulating board 21 and third insulating board 31) where the voltage is not applied, a pressure loss of the air blowing system can be restricted from increasing. Thus, the air-blowing capacity of the air blowing system can be improved.

Moreover, because the insulating film can be readily formed at the thermoelectric element 12 (13) which is arranged at the inner side and readily formed at the joining portion between the heat exchanging member 22 (32) and the thermoelectric element 12 (13), the migration can be restricted.

In this case, each of the heat-exchanging members 22 and 32 is constructed of the thin plate and provided with the multiple edge surfaces which have the acute angle, to function as the heat absorbing portion or the heat radiating portion. The insulating material includes the edge-cover resin material, which is the resin material having a high viscosity when being melted in the insulating material in the electrodeposition sink. Thus, when the thermoelectric element substrate unit 10 (where insulating material has been applied in electrodeposition sink) is taken out from the electrodeposition sink to be baked, the liquid drooping from the edge surface can be reduced. Therefore, the insulating film having the predetermined thickness can be formed.

According to this embodiment, the baking process is performed after the immersion process is performed several times, so that the insulating material can be applied to the part where the insulating material has not been applied last time. Therefore, the insulating film having the predetermined thickness can be thoroughly provided.

As described above, the immersion condition in the immersion process includes the applying voltage, the immersion period of time and the immersion times and the like. In the immersion process which is performed several times, the immersion condition can be changed with respect to the different times so that the insulating film having the predetermined thickness can be evenly formed.

The baking condition in the baking process includes the baking temperature, the baking period of time and the baking times. The baking process can be repeated several times, and the baking condition can be changed with respect to the different times. Therefore, the insulating film having the predetermined thickness can be evenly formed.

According to this embodiment, the thermoelectric conversion device 100 can be suitably used for the seat air-conditioning device. However, the thermoelectric conversion device 100 is not limited to the use for the vehicle. For example, the thermoelectric conversion device 100 can be also used for a cooling device or a heating device for cooling or heating blown air from a Peltier element.

### Second Embodiment

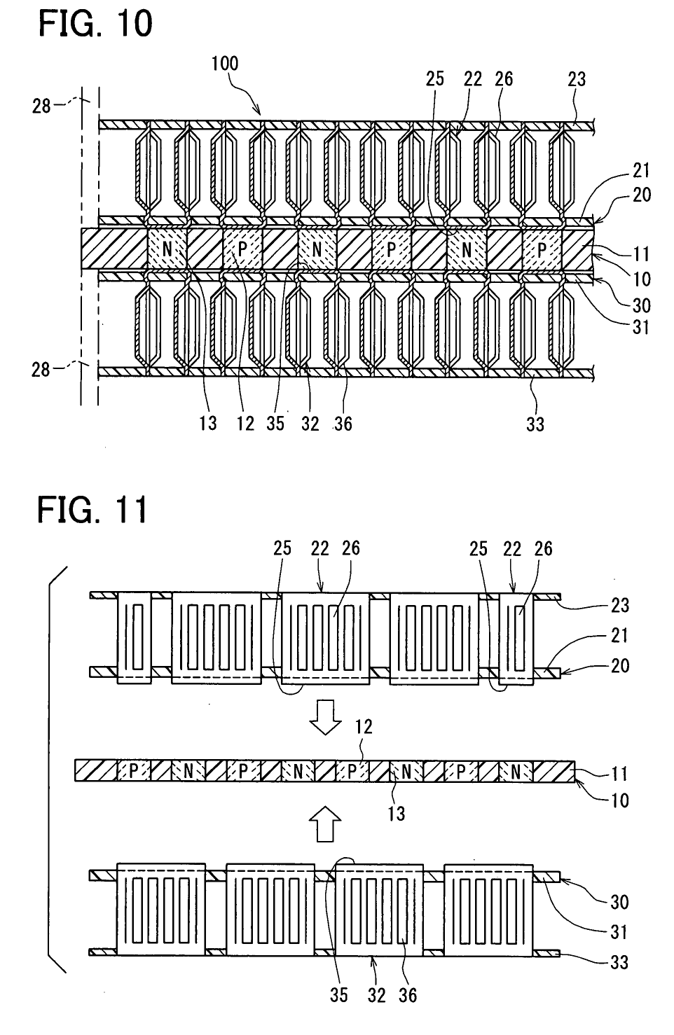

A second embodiment of the present invention will be described with reference to FIGS. 9-11. In this embodiment, the electrode members 16 in the thermoelectric conversion device 100 are omitted.

According to the second embodiment, the heat-absorbing electrode portion 25 of the heat exchanging member 22 and the heat-radiating electrode portion 35 of the heat exchanging member 32 double as the electrode member. In this case, the electrode portion 25 (35) directly contacts the pair of the thermoelectric elements 12 and 13 which are arrayed at the insulating substrate 11 and are adjacent to each other, to be electrically connected in series with the thermoelectric elements 12 and 13.

Specifically, the heat-absorbing electrode portion 25 which is arranged at the upper side constructs the electrode through which the current flows from the thermoelectric element 13 to the thermoelectric element 12 (adjacent to this thermoelectric element 13), the heat-radiating electrode portion 35 which is arranged at the lower side constructs the electrode through which the current flows from the thermoelectric element 12 to the thermoelectric element 13 (adjacent to this thermoelectric element 12).

In this case, the paste solder can be beforehand applied to the end surfaces of the thermoelectric element 12, 13 by screen printing to be thin and evenly applied. Thus, the heat-absorbing electrode portion 25 and the heat-radiating electrode portion 35 can be joined to the end surfaces of the thermoelectric element 12, 13 by soldering.

Therefore, the component cost and the assembling cost can be reduced, due to the omission of the electrode member 16.

About the thermoelectric conversion device 100 and the manufacture method thereof, what has not been described in the second embodiment can be the same with the first embodiment.

### Third Embodiment

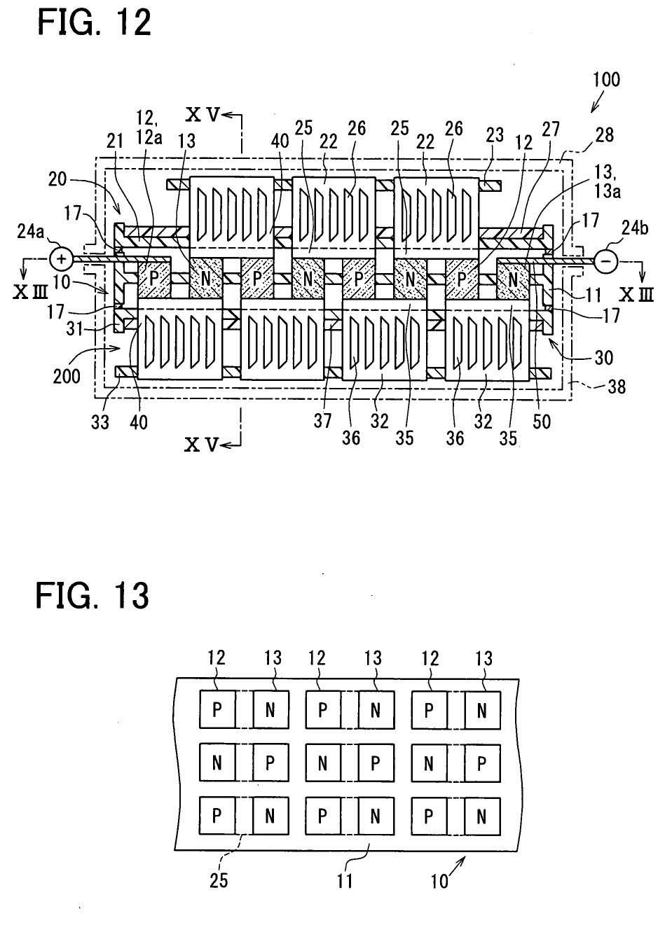

A third embodiment of the present invention will be described with reference to FIGS. 12-17.

As shown in FIG. 12, the thermoelectric conversion device 100 includes a thermoelectric conversion module 200 which is provided with the thermoelectric element substrate unit 10, the first fin board unit 20 and the second fin board unit 30, and the case members 28 and 38 in where the thermoelectric conversion module 200 is accommodated.

With reference to FIGS. 12-15, the thermoelectric element substrate unit 10 has the multiple p-type thermoelectric elements 12 and the multiple N-type thermoelectric elements 13, and the insulating substrate 11 (holding member) which are integrated with each other. Specifically, the multiple engagement holes are arranged in the pattern of substantial lattice of uniform squares, at the insulating substrate 11 made of the insulating material (for example, glass epoxy, phenol resin, PPS resin, LCP resin or PET resin) having a plate shape. The multiple thermoelectric elements 12 and 13 are arranged at the engagement holes, and alternatively arrayed at the insulating substrate 11.

The two end surfaces (for example, upper end surface and lower end surface) of each of the thermoelectric elements 12 and 13 protrude from the insulating substrate 11. In this embodiment, the thermoelectric element 12 and 13 having a size of about 1.5 mm-squar are held at the insulating substrate 11.

As shown in FIGS. 12, 14 and 15, the first fin board unit 20 includes the multiple heat exchanging members 22 (for absorbing heat), the insulating board 21 (first holding member) and the fixing member 23 (second holding member) which are integrated with each other. The insulating board 21 can be made of the substantially plate-shaped insulating material (for example, glass epoxy, phenol resin, PPS resin, LCP resin or PET resin).

The second fin board unit 30 includes the heat-exchanging member 32 (for radiating heat), the fixing member 33 (second holding member) and the third insulating board 31 (first holding member) which are integrated with each other. The third insulating board 31 (first holding member) can be made of the substantially plate-shaped insulating material (for example, glass epoxy, phenol resin, PPS resin, LCP resin or PET resin).

Specifically, each of the insulating board 21, the fixing member 23, the third insulating board 31 and the fixing member 33 is provided thereat the multiple engagement holes which are arrayed in the pattern of substantial lattice of uniform squares. The heat exchanging members 22 are held at the engagement holes of the insulating board 21 and the fixing member 23, and the heat exchanging members 32 are held at the engagement holes of the third insulating board 31 and the fixing member 33. Thus, the heat exchanging members 22 which are adjacent to each other can be spaced from each other at the predetermined distance and electrically insulated from each other, and the heat exchanging members 32 which are adjacent to each other can be spaced from each other at the predetermined distance and electrically insulated from each other.

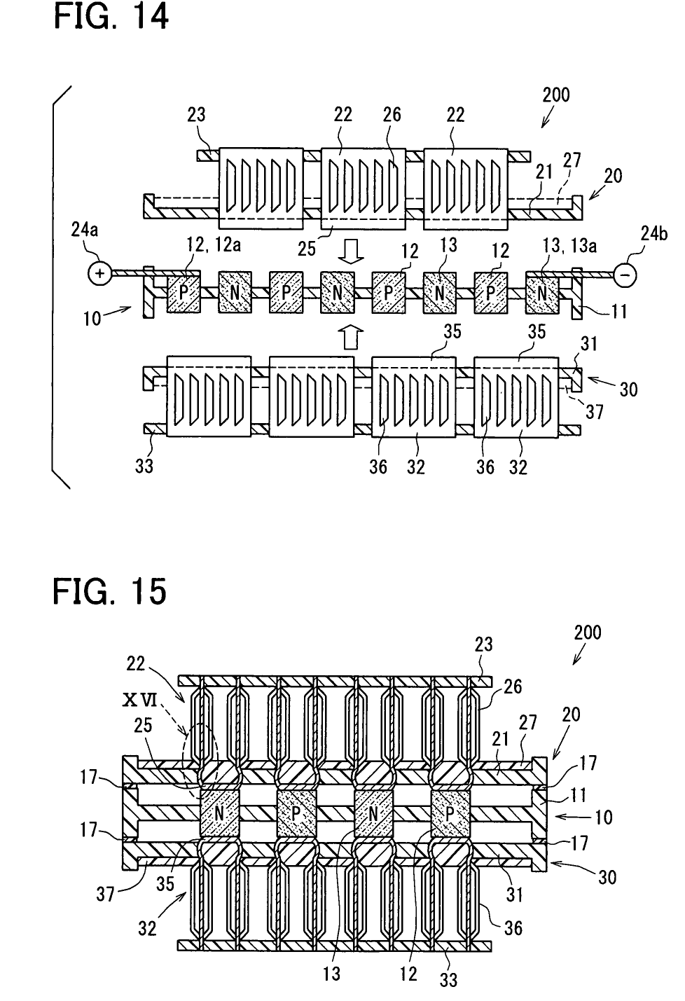

The electrode member 22, 32 can be constructed of a thin plate material made of a conductive metal such as copper or the like, and shaped to have a U-like cross section as shown in FIG. 15. The bottom portion of the U-like electrode member 22 and that of the U-like electrode member 32 respectively construct the heat-absorbing electrode portion 25 and the heat-radiating electrode portion 35 (which have substantial plate shape, for example).

Furthermore, the electrode members 22 and 32 are respectively provided with the heat exchanging portion 26 (heat absorbing portion) and the heat exchanging portion 36 (heat radiating portion). The heat exchanging portion 26, 36 extends outward from the electrode portion 25, 35, and has the louver shape. For example, the electrode member 22, 32 can be constructed of a plate material having a thickness of about 0.2 mm-0.3 mm, to have a desirable manufacture performance.

The electrode portion 25 of the heat exchanging member 22 and the electrode portion 35 of the heat exchanging member 32 are respectively joined (by soldering, for example) to the thermoelectric element 12 and the thermoelectric element 13 of the thermoelectric element substrate unit 10. Specifically, as shown in FIGS. 12, 14 and 15, the heat exchanging member 22 is joined to the first end surfaces (e.g., upper end surfaces) of the thermoelectric element 12 and the thermoelectric element 13, and the heat exchanging member 32 is joined to the second end surfaces (e.g., lower end surfaces) of the thermoelectric element 12 and the thermoelectric element 13.

The electrode portions 25 and 35 are electrodes for electrically connecting the thermoelectric element 12 with the thermoelectric element 13 which are adjacent to each other. Specifically, as shown in FIG. 12, the thermoelectric element 13 is connected with the thermoelectric element 12 by the electrode portion 25 in such a manner that the electrical current flows from the thermoelectric element 13 to the thermoelectric element 12 (which is adjacent to the thermoelectric element 13).

The thermoelectric element 13 is connected with the thermoelectric element 12 by the electrode portion 25 in such a manner that the electrical current flows from the thermoelectric element 12 to the thermoelectric element 13 (which is adjacent to the thermoelectric element 12). Thus, all of the thermoelectric elements 12 and 13 are connected with each other in series to construct a series circuit 50.

The heat exchanging portions 26 and 36 can be constructed of fins for transmitting heat absorbed/radiated through the electrode portions 25 and 35. In this case, heat can be absorbed through the heat exchanging portion 26 (heat absorbing portion) from fluid or the like contacting the heat exchanging portion 26, and heat can be radiated through the heat exchanging portion 36 (heat radiating portion) to fluid contacting the heat exchanging portion 36.

The heat exchanging portions 26 and 36 can be formed by respectively lancing the surfaces extending outward from the electrode portions 25 and 35, for example. In this embodiment, the heat exchanging portion 26 and the electrode portion 25 are integrated with each other to construct the heat exchanging member 22, and the heat exchanging portion 36 and the electrode portion 35 are integrated with each other to construct the heat exchanging member 32.

The electrode portion 25 of the heat exchanging member 22 is constructed to slightly protrude from the insulating board 21 to the side of the thermoelectric element 12, and the heat exchanging portion 26 is not exposed to the side of the thermoelectric element 12. Similarly, the electrode portion 35 of the heat exchanging member 32 is constructed to slightly protrude from the second insulating board 31 to the side of the thermoelectric element 13, and the heat exchanging portion 36 is not exposed to the side of the thermoelectric element 13.

The tip portions of the electrode members 22 and 32 are respectively held by the fixing members 23 and 23. In this case, the end portion of the heat exchanging member 22 slightly protrudes from the upper surface of the fixing member 23, and the end portion of the heat exchanging member 32 slightly protrudes from the lower surface of the fixing member 33.

The thermoelectric element 12 and the thermoelectric element 13 (respectively indicated by 12a and 13a shown in FIGS. 12 and 14) which are respectively arranged at two ends (of direction in which electrode members 22 and 32 are arrayed) of the series circuit 50 are respectively provided with the connection terminals 24a and 24b. The series circuit 50 includes the electrode portions 25 and 35 connected with each other.

The connection terminal 24a and the connection terminal 24b can be respectively connected with the positive terminal and the negative terminal of the direct-current power source (not shown).

According to the thermoelectric conversion module 200 described in this embodiment, when a voltage is applied to the connection terminal 24a, direct current will flow in the series circuit 50 between the thermoelectric element 12a and the thermoelectric element 13a in such a manner that the direct current flows from the thermoelectric element 12a to the thermoelectric element 13 (which is adjacent to thermoelectric element 12a) through the electrode portion 35 and further flows from the thermoelectric element 13 to the thermoelectric element 12 through the electrode portion 25.

In this case, the electrode portion 35 which is arranged at the PN joining portion has a high temperature state due to a Peltier effect, and the electrode portion 25 arranged at the NP joining portion has a low temperature state. Thus, the heat from the electrode portion 35 is transmitted to the heat exchanging portion 36 of the heat exchanging member 32, and radiated to the cooling fluid (heat transfer media such as air) which contacts the heat exchanging portion 36. The heat absorbed from the electrode portion 25 is transmitted to the heat exchanging portion 26 of the heat exchanging member 22, and absorbed by the cooling fluid (heat transfer media such as air) which contacts the heat exchanging portion 26.

Thus, as shown FIG. 12, the case members 28 and 38 respectively construct the air passages (which are partitioned from each other by thermoelectric element substrate unit 10) at the two sides of the thermoelectric element substrate unit 10, that is, the side of the heat exchanging member 22 and the side of the heat exchanging member 32. Air (heat transfer media) flows through the air passage to heat-exchange with the heat exchanging portion 26 and the heat exchanging portion 36. Therefore, the air flowing through the air passage of the side of the heat exchanging member 22 is cooled and air flowing through the air passage of the side of the heat exchanging member 32 is heated.

In this case, the heat exchanging portions 26 and 36 of the thermoelectric conversion device 100 are respectively connected with the electrode portions 25 and 35, without being insulated from the electrode portions 25 and 35. The electrode portion 25 constructs a heat absorption portion of the series circuit 50, and the electrode portion 35 constructs a heat-radiation portion of the series circuit 50. Therefore, a heat-exchanging efficiency can be improved. However, when the voltage is applied to the connection terminal 24a and the connection terminal 24b, a potential is applied to the whole conductive part (heat exchanging portion 26, heat exchanging portion 36 and the like) which is connected with the series circuit 50 without being insulated. That is, the potential is not applied to only the series circuit 50, which includes the thermoelectric elements 12 and 13.

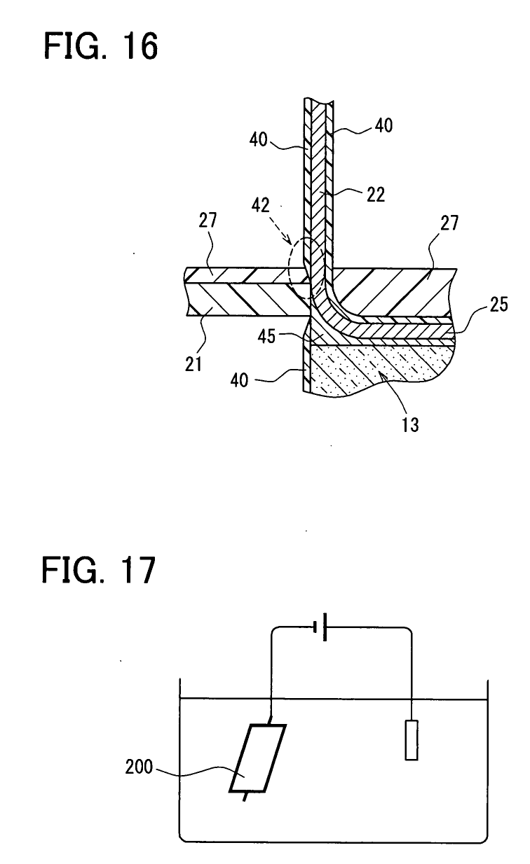

As shown in FIG. 16, in the thermoelectric conversion device 100, an insulating film 40 (insulating layer) for preventing a short circuit is arranged at the substantially whole surface of the conductive part, where the potential is applied when the voltage is applied to the connection terminal 24a and the connection terminal 24b of the thermoelectric conversion module 200.

The insulating film 40 can be formed by electrodeposition coating, for example. The insulating film 40 can be evenly formed at the substantial whole of the exposed surface of the conductive part (which is connected with series circuit 50 without being insulated) such as the surfaces of the heat exchanging portions 26 of the heat exchanging member 22 and the heat exchanging portion 36 of the heat exchanging member 32, the side surfaces of the thermoelectric element 12 and the thermoelectric element 13, the side surfaces of joining portions 45 (between electrode portion 25 and thermoelectric elements 12, 13 and between electrode portion 35 and thermoelectric elements 12, 13) and the like. The insulating film 40 is formed along the shape of this exposed surface of the conductive part. In this embodiment, the insulating film 40 can be formed by an epoxy resin coating, and provided with a film thickness of about 10 μm-20 μm, for example.

FIG. 16 shows the contact portion 42 between the insulating board 21 and the heat exchanging member 22 of the electrode board unit 20. In this case, the contact portion between the insulating board 31 and the heat exchanging member 32 of the electrode board unit 30 can be provided with a substantially same construction as what is shown in FIG. 16.

Moreover, as shown in FIGS. 12 and 14-16, a first seal layer 27 (seal member) and a second seal layer 37 (seal member) are respectively formed at surfaces (which are at the opposite side to the thermoelectric element substrate unit 10) of the insulating board 21 and the third insulating board 31. As shown in FIG. 15, the seal layer 27 is formed at the substantially whole surface (of the side of heat exchanging portion 26) of the insulating board 21, to reach the inner side (i.e., back side of electrode portion 25) of the engagement portion of the heat exchanging member 22 with the insulating board 21. The seal layer 37 is formed at the substantially whole surface (of the side of heat exchanging portion 36) of the insulating board 31, to reach the inner side (i.e., back side of electrode portion 35) of the engagement portion of the heat exchanging member 32 with the insulating board 31. In this embodiment, the seal layer 27, 37 can be constructed of an epoxy resin seal material or the like, and provided with a thickness of about 2 mm-3 mm, for example.

As shown in FIG. 16, the seal layer 27 is formed to cover the insulating film 40 from the outer side at the contact portion between the insulating board 21 and the root portion of the heat exchanging member 22. Similarly, the seal layer 37 is formed to cover the insulating film 40 from the outer side at the contact portion 42 between the insulating board 31 and the root portion of the fixing member 33.

Thus, because the seal layers 27 and 37 are provided, the insulation in the vicinity of the insulating substrates 21 and 31 where it is difficult for the insulating film 40 to be formed by the electrodeposition coating at the heat exchanging portions 26 and 36 can be reinforced. Moreover, the seal layers 27 and 37 can restrict intrusion of water or the like upon the side of the thermoelectric element substrate unit 10.

Next, the manufacture method of the thermoelectric conversion device 100 will be described. The manufacture method can include a joining process (with reference to FIG. 14), an electrodeposition coating process (which corresponds to immersion process and baking process in first embodiment and is shown in FIG. 17), and a sealing process.

In the joining process, at first, the thermoelectric elements 12 and 13 are alternately arrayed and fixed by an adhesive or the like at the multiple engagement holes which are arrayed at the insulating substrate 11 in the pattern of the substantial lattice of uniform squares. Thus, the thermoelectric element substrate unit 10 is constructed. In this case, the attachment of the thermoelectric elements 12 and 13 to the insulating substrate 11 can be performed by using, for example, the mounter device.

On the other hand, the root portions of the electrode members 22 are engaged with the multiple holes which are formed at the insulating board 21 and arranged in the pattern of the substantial lattice of uniform squares, to be held in the holes. Moreover, the end portions of the electrode members 22 are engaged with the engagement holes formed at the fixing member 23. Thus, the fin board unit 20 of heat-absorbing side is produced.

Similarly, the root portions of the electrode members 32 are engaged with the multiple holes which are formed at the insulating board 31 and arranged in the pattern of the substantial lattice of uniform squares, to be held in the holes. Moreover, the tip portions of the electrode members 32 are engaged with the engagement holes formed at the fixing member 33. Thus, the fin board unit 30 of heat-radiating side is constructed.

The heat exchanging member 22 is arranged in such a manner that the electrode portion 25 of the heat exchanging member 22 slightly protrudes from the insulating board 21. The heat exchanging member 32 is arranged in such a manner that the electrode portion 35 of the heat exchanging member 32 slightly protrudes from the insulating board 31.

Moreover, the tip portions of the electrode members 22 and 32 are respectively held in the engagement holes of the fixing member 23 and those of the fixing member 33. In this case, the tip portion of the heat exchanging member 22 slightly protrudes from the upper surface (of opposite side of fixing member 23 to thermoelectric element substrate unit 10) of the fixing member 23, and the tip portion of the heat exchanging member 32 slightly protrudes from the lower surface (of opposite side of fixing member 33 to thermoelectric element substrate unit 10) of the fixing member 33.

The electrode members 22 and 32 can be beforehand formed. For example, the heat exchanging member 22, 32 can be constructed of a metal plate material and manufactured by pressing process or the like to have the substantially U-like shape. The bottom portion of the U-like shape constructs the electrode portion 25, 35 having a substantial plate shape. The heat exchanging portions 26 and 36 having the louver shape respectively extends outward from the electrode portions 25 and 35.

Then, as shown in FIG. 14, the thermoelectric element substrate unit 10 is inserted between the fin board unit 20 of heat-absorbing side and the fin board unit 30 of heat-radiating side to be assembled, so that the thermoelectric conversion module 200 is constructed. Specifically, the electrode portion 25 of the heat exchanging member 22 is joined by soldering or the like to the upper end surface of the thermoelectric element 12 and the electrode portion 35 of the heat exchanging member 32 is joined by soldering or the like to the lower end surface of the thermoelectric element 13, so that the thermoelectric elements 12 and 13 are respectively joined to the electrode members 22 and 32. In this case, the paste solder or the like can be thinly and evenly applied by screen printing to the upper surface of the thermoelectric element 12 and the lower surface of the thermoelectric element 13, and the electrode portions 25 and 35 are joined by soldering or the like to the thermoelectric elements 12 and 13.

For the thermoelectric conversion module 200 constructed as described above, at the electrodeposition coating process, the insulating film 40 is formed (by electrodeposition coating) at the substantially whole surface of the conductive part, where a potential will be applied when a voltage is applied to the connection terminals 24a and 24b. Specifically, as shown in FIG. 17, the thermoelectric conversion module 200 is soaked in a sink where a solution of the epoxy resin paint is provided, and a voltage is applied to one (as negative pole) of the connection terminal 24a and the connection terminal 24b. After the paint is applied to the thermoelectric conversion module 200, the thermoelectric conversion module 200 is heated at a temperature about 180° C.-190° C., for example, so that the coating layer 40 (insulating film) is formed by baking the paint.

Thus, as shown in FIG. 16, the paint is selectively applied to the surface (for example, surfaces of electrode members 22 and 32, side surfaces of thermoelectric elements 12 and 13, side surface of solder joining portion 45 and the like) of the conductive part when the voltage is applied to the connection terminals 24a and 24b. As a result, the insulating film 40 (where pin holes can be restricted) is substantially evenly formed at the substantially whole surface of this conductive part. In this embodiment, the insulating film 40 having a thickness of about 10 μm-20 μm can be provided, for example.

In this embodiment, the voltage can be applied to the one (as negative pole) of the connection terminal 24a and the connection terminal 24b of the thermoelectric conversion module 200 when the electrodeposition coating is performed. Alternatively, the electrodeposition coating can be similarly performed with the voltage being applied at any position, if this position is in the conductive part where a potential is applied when a voltage is applied to the connection terminals 24a and 24b of the thermoelectric conversion module 200.

Moreover, in this embodiment, the electrodeposition coating is performed with applying the voltage to the thermoelectric conversion module 200 as the negative pole. Alternatively, the voltage can be also applied to the thermoelectric conversion module 200 as a positive pole in response to the used paint.

Next, at the sealing process, the seal layer 27 and the seal layer 37 are respectively formed at the surfaces (at opposite side to the thermoelectric element substrate unit 10) of the insulating board 21 and the insulating board 31 as shown in FIGS. 12, 15 and 16. Specifically, the seal material such as the epoxy resin or the like is infused onto the insulating substrates 21 and 31 through a dispenser, and then the insulating substrates 21 and 31 are arranged in a high temperature sink so that the seal material are hardened. Thus, the seal layer 27 and the seal layer 37 are formed. In this embodiment, the seal layer 27, 37 can be provided with a thickness of about 2 mm-3 mm, for example.

Furthermore, as shown in FIGS. 12 and 15, the seal material can be applied to the gaps 17 (at periphery portions of insulating substrates 21 and 31) between the thermoelectric element substrate unit 10 and the insulating board 21, 31 too, so that a seal for restricting the intrusion of water and the like to the side of the thermoelectric element substrate unit 10 is provided.

Thereafter, the case member 28 and the case member 38 are arranged to cover the thermoelectric conversion module 200, and respectively positioned at the two opposite sides (e.g., upper side and lower side in FIG. 1) of the thermoelectric conversion module 200, so that the heat exchanging portion for heat-absorbing and that for heat-radiating where air flows are formed. In this case, a packing (not shown) is filled in the gap between the tip portion (fixing member 23) of the heat exchanging member 22 and the case member 28 and the gap between the tip portion (fixing member 33) of the heat exchanging member 32 and the case member 38, so that the position of the thermoelectric conversion module 200 in the case member 28 and the case member 38 is fixed.

Thus, in the thermoelectric conversion device 100, the insulating film 40 is formed by electrodeposition coating at the substantially whole surface of the conductive part where the potential is applied when the voltage is applied to the connection terminals 24a and 24b. In this case, the thermoelectric conversion module 200 is firstly constructed, and then the electrodeposition coating is performed at the thermoelectric conversion module 200 so that the insulating film 40 can be selectively formed at the conductive part where the insulation is necessary. Moreover, the substantially whole surface of the conductive part where the insulation is necessary can be provided with the insulating film 40 at a same stage. Because the electrodeposition coating is provided, the insulating film 40 where the pin holes are reduced can be substantially formed at the heat exchanging portion 26 and the heat exchanging portion 36 or the like which have a complex shape, thus restricting the ion-migration and the short circuit at the conductive part.

Furthermore, in the thermoelectric conversion device 100 according to this embodiment, the seal layer 27, 37 is formed at the vicinity of the contact portion 42 between the insulating board 21 and the heat exchanging member 22 and that between the third insulating board 31 and the heat exchanging member 32 where it is difficult to form the insulating film 40 by the electrodeposition coating, in such a manner that the seal layer 27, 37 covers the contact portion 42 from the outer side of the insulating film 40. Thus, the insulating film 40 is reinforced, so that the insulation of the conductive part (in the thermoelectric conversion device 100) where the insulation is necessary can become substantially complete. Therefore, the ion-migration and the short circuit in the thermoelectric conversion device 100 can be substantially restricted.

In this case, the seal layer 27, 37 is formed to cover the substantially whole surface of the insulating board 21, 31 at the protrusion side of the heat exchanging member 22, 32, thus restricting the intrusion of water droplet adhered to the heat exchanging portion 26, 36 due to the water condensation at the heat-absorbing side, water vapor, medicine, dust, foreign matter and the like included in air flowing through the heat exchanging portion 26, 36 upon the side of the thermoelectric element 12, 13 from the gap or the like of the engagement portion between the insulating board 21 and the heat exchanging member 22 and that between the third insulating board 31 and the heat exchanging member 32. Thus, the corrosion, damage, ion-migration and short circuit can be restricted from occurring at the thermoelectric element 12, 13 and the heat-absorbing electrode portion 25, 35.

About the thermoelectric conversion device 100 and the manufacture method thereof, what has not been described in the third embodiment can be the same with the first embodiment.

### Fourth Embodiment

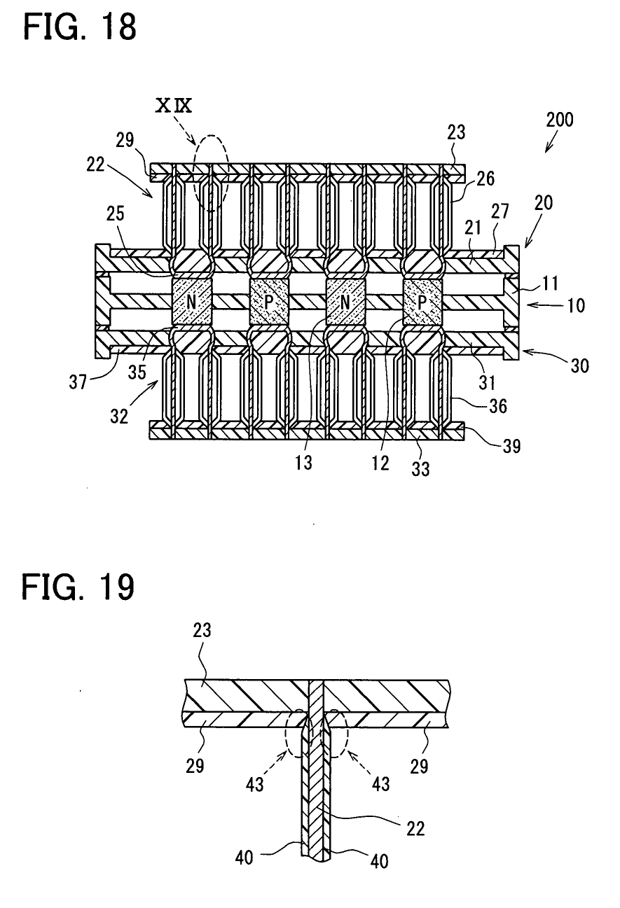

A fourth embodiment of the present invention will be described with reference to FIGS. 18 and 19. In the above-described third embodiment, the seal layers 27 and 37 are respectively arranged at the surfaces of the insulating substrates 21 and 31 where the roots portions of the electrode members 22 and 32 are respectively held. According to the second embodiment, as show in FIG. 18, in addition to the seal layers 27 and 37, a third seal layer 29 and a fourth seal layer 39 are respectively arranged at the surfaces of the fixing member 23 and the fixing member 33 where the tip portions of the electrode members 22 and 32 are held.

The third seal layer 29 is formed at the substantially whole of the surface (of the side of heat exchanging portion 26) of the fixing member 23, and the fourth seal layer 39 is formed at the substantially whole of the surface (of the side of heat exchanging portion 36) of the fixing member 33. In this embodiment, the seal layer 29, 39 can be provided with a thickness of about 2 mm-3 mm, for example.

With reference to FIGS. 18 and 19, the third seal layer 29 is provided at the contact portion 43 between the tip portion of the heat exchanging portion 26 and the fixing member 23, in such a manner that the third seal layer 29 covers the insulating film 40 from the outer side. Thus, insulation of the part where it is difficult to form the insulating film 40 at the heat exchanging portion 26 by the electrodeposition coating can be reinforced to become substantially complete.

The contact portion 43 (shown in FIG. 19) between the heat exchanging member 22 and the fixing member 23 has the similar construction to the contact portion 43 between the heat exchanging member 32 and the fixing member 33. The fourth seal layer 39 can be provided with the same construction as the third seal layer 29.

The third seal layer 29 and the fourth seal layer 39 can be formed together with the first seal layer 27 and the second seal layer 37 at the adhesive layer forming process which is performed similarly to the third embodiment. Specifically, an epoxy resin seal material is applied to the surfaces of the fixing members 23 and 33, and then the fixing members 23 and 33 are hardened so that the third seal layer 29 and the fourth seal layer 39 are formed.

According to this embodiment, the third seal layer 29 and the fourth seal layer 39 are respectively provided at the substantially whole surfaces (of the sides of heat exchanging members 22 and 32) of the fixing member 23 and the fixing member 33 where the tip portions of the electrode member 22 and the electrode member 32 are held, thus reinforcing the insulation of the vicinity of the exposure portion 43 (at the fixing member 23, 33 positioned at the tip portion of the electrode member 22, 32) where it is difficult to form the insulating film 40 by the electrodeposition coating. Therefore, the insulation at the side of the tip portion of the electrode member 22, 32 can become substantially complete. Accordingly, the short circuit in the thermoelectric conversion device 100 and the ion-migration can be substantially restricted.

About the thermoelectric conversion device 100 and the manufacture method thereof, what has not been described in the fourth embodiment can be the same with the first embodiment.

### Fifth Embodiment

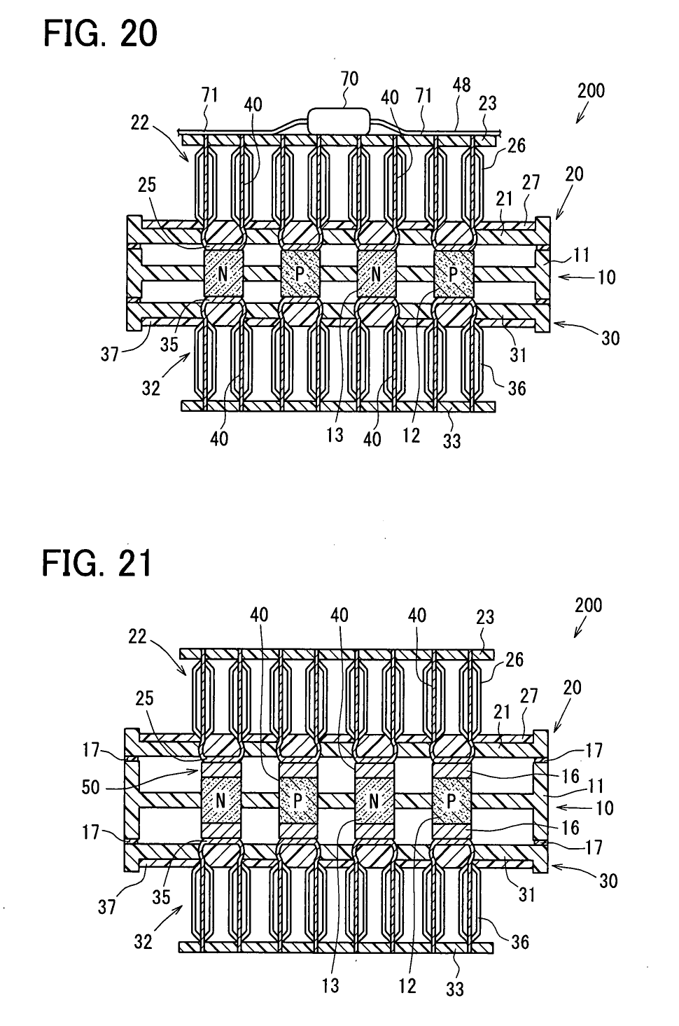

A fifth embodiment of the present invention will be described with reference to FIG. 20. According to this embodiment, a temperature sensor 70 (for example, thermistor) is additionally arranged at the surface (of opposite side to electrode member 22) of the fixing member 23.

The thermistor 70 is arranged at the fixing member 23 to contact the tip portion of the electrode member 22. A lead 71 (wiring) for connecting the thermistor 70 with an exterior control unit (not shown) is arranged at the fixing member 23. The lead 71 can be constructed of a conductive metal wire, for example. An insulating film 48 (wiring insulation layer) is formed at the surface of the lead 71 by the electrodeposition coating, for example.

The thermistor 70 can be fixed to the fixing member 23 by an adhesive or the like and the lead 71 can be joined to the fixing member 23 by soldering or the like, at the joining process similar to the third embodiment.

Thus, at the electrodeposition coating process similar to the third embodiment, when the insulating film 40 is formed at the thermoelectric conversion module 200, the voltage is applied not only to the one connection terminal (which is used as negative pole and not shown) of the thermoelectric conversion module 200, but also to the lead 71 (which is used as negative pole) of the thermistor 70. Accordingly, because the electrodeposition coating is performed, the insulating film 48 can be also formed at the lead 71 of the thermistor 70 concurrently with the forming of the insulating film 40 at the conductive portion of the thermoelectric conversion module 200.

In this embodiment, the thermistor 70 can be arranged to contact the electrode member 22. However, the arrangement position of the thermistor 70 is not limited. For example, the thermistor 70 can be also positioned in the vicinity of the electrode member 22, or positioned at the side of the electrode member 32, according to the need.

Thus, in the case where the thermoelectric conversion module 200 is provided with the thermistor 70 and the lead 71, the insulating film 48 can be concurrently formed at the lead 71 of the thermistor 70 which is arranged at the thermoelectric conversion module 200 when the insulating film 40 is formed at the surface of the conductive part of the thermoelectric conversion module 200 by the electrodeposition coating. Therefore, the ion-migration and the short circuit in the thermoelectric conversion device 100 can be substantially restricted, even when water intrudes upon the lead 71.

About the thermoelectric conversion device 100 and the manufacture method thereof, what has not been described in the fifth embodiment can be the same with the first embodiment.

### Sixth Embodiment

A sixth embodiment of the present invention will be described with reference to FIG. 21. In the above-described embodiments, the thermoelectric element 12 and the thermoelectric element 13 are directly connected with each other by the electrode portion 25 of the electrode member 22 and the electrode portion 35 of the heat exchanging member 32. According to the sixth embodiment, as shown in FIG. 21, an electrode portion 16 other than the heat exchanging members 22 and 32 can be arranged to connect the thermoelectric element 12 with the thermoelectric element 13 which are adjacent to each other.

In this case, each of the electrode portion 25 of the heat exchanging member 22 and the electrode portion 35 of the heat exchanging member 32 is joined to the electrode portion 16. Specifically, in the joining process similar to what is described in the third embodiment, the electrode portions 16 are respectively joined by soldering to the upper end surface and the lower surface of the thermoelectric element 12 and those of the thermoelectric element 13 after the thermoelectric element 12 and the thermoelectric element 13 are attached to the insulating substrate 11.

Thus, the manufacture of the thermoelectric element substrate unit 10 is finished. Then, when the fin board unit 20 of heat-absorbing side and the fin board unit 30 of heat-radiating side are joined to the thermoelectric element substrate unit 10 to construct the thermoelectric conversion module 200, the electrode portion 25 of the heat exchanging member 22 and the electrode portion 35 of the heat exchanging member 32 are joined to the electrode portions 16. The electrode portion 16 can be constructed of a conductive metal such as copper or the like and have a substantially plate shape, for example.

Then, the thermoelectric conversion module 200 can be provided with the electrodeposition coating similarly to the electrodeposition coating process of the third embodiment. Thus, the insulating film 40 is formed at the surfaces of the heat exchanging portions 26 and 36 and the side surfaces of the thermoelectric elements 12 and 13. Furthermore, the insulating film 40 is also formed at the side surface of the solder joining portion between the electrode portion 16 and the thermoelectric element 12 and that between the electrode portion 16 and the thermoelectric element 13, the side surface of the electrode portion 16, the side surface of the solder joining portion between the electrode portion 16 and the electrode portion 25 of the heat exchanging member 22 and that between the electrode portion 16 and the electrode portion 35 of the heat exchanging member 32.

According to this embodiment, the electrode portion 16 other than the heat exchanging member 22 and the heat exchanging member 32 are provided. Because the series circuit 50 has been constructed due to the connection of the thermoelectric element 12 with the thermoelectric element 13 through the electrode portion 16 when the manufacture of the thermoelectric element substrate unit 10 is finished, an electrical inspection of the series circuit 50 and a faulty conduction and the like between the electrode portion 16 and the thermoelectric element 12, 13 can be readily performed for the thermoelectric element substrate unit 10 before the thermoelectric conversion module 200 are assembled.

About the thermoelectric conversion device 100 and the manufacture method thereof, what has not been described in the sixth embodiment can be the same with the first embodiment.

### Other Embodiment

Although the present invention has been fully described in connection with the preferred embodiments thereof with reference to the accompanying drawings, it is to be noted that various changes and modifications will become apparent to those skilled in the art.

In the first embodiment, the two end portions (root portion and tip portion) of the heat exchanging member 22 are respectively fixed to the insulating board 21 and the fixing member 23, and those of the heat exchanging member 32 are respectively fixed to the insulating board 31 and the fixing member 33. However, the fixing member 23 and the fixing member 33 can be also omitted. In this case, the heat exchanging member 22 and the heat exchanging member 32 are respectively held by the insulating board 21 and the insulating board 31 only at the root portions thereof which are fixed to the insulating substrates 21 and 31. Alternatively, the insulating substrates 21 and 31 can be also omitted. In this case, the heat exchanging member 22 and the heat exchanging member 32 are respectively held by the fixing member 23 and the fixing member 33 only at the tip portions thereof which are fixed to the fixing member 23 and the fixing member 33.

In the above-described embodiments, the thermoelectric elements 12 and 13 are held at the insulating substrate 11 (holding member) to construct the thermoelectric element substrate unit 10. Alternatively, the insulating substrate 11 can be also omitted. In this case, for example, the thermoelectric element 12, 13 can be joined to one of the electrode portion 25 of the heat exchanging member 22 and the electrode portion 35 of the heat exchanging member 32.

In the above-described embodiments, the heat exchanging portion 26 of the heat exchanging member 22 and the heat exchanging portion 36 of the heat exchanging member 32 are formed to have the louver shape. However, the heat exchanging portion 26 and the heat exchanging portion 36 can also have an offset shape. Alternatively, corrugated fins each of which is constructed of a corrugated metal plate or the like can be provided in each of the heat exchanging member 22 and the heat exchanging member 32 which have a comb teeth shape, to construct the heat exchanging portion 26 and the heat exchanging portion 36.

In the above-described embodiments, the positive terminal of the direct current power source is connected with the connection terminal 24a, and the negative terminal thereof is connected with the connection terminal 24b. Alternatively, the positive terminal of the direct current power source can be also connected with the connection terminal 24b, and the negative terminal thereof can be also connected with the connection terminal 24a. In this case, the heat exchanging member 22 of the upper side constructs a heat radiating portion, and the heat exchanging member 32 of the lower side constructs a heat absorbing portion.

That is, the heat absorbing side and the heat radiating side can be switched, by switching the flowing direction of the current flowing in the series circuit 50 constructed of the thermoelectric elements 12 and 13. Thus, the thermoelectric conversion device can be used to cool a heat-producing component such as a semiconductor or electrical component or the like, and cool/heat in an air conditioning device.

Moreover, in the above-described embodiments, the insulating film 40 (electrodeposition coating layer) formed by the electrodeposition coating or the insulating film 41 (vapor deposition layer) formed by vapor deposition is provided as the insulating film. Alternatively, the thermoelectric conversion module can be also immersed in the insulating paint, and then the thermoelectric conversion module is heated and dried so that the insulating film (paint layer) is formed at the surfaces of the heat exchanging portion 26 and the heat exchanging portion 36.

Moreover, the adhesive layer 27 and the adhesive layer 37 can be also constructed of a silicon adhesive.

Furthermore, in the above-described embodiments, the adhesive layers 27 and 37 are formed to respectively cover the substantially whole surface of the insulating board 21 and that of the insulating board 31. However, the adhesive layers 27 and 37 can be also respectively pin-point formed in the vicinity of the exposure portion 42 of the heat exchanging portion 26 and that of the heat exchanging portion 36.

Such changes and modifications are to be understood as being in the scope of the present invention as defined by the appended claims.

What is claimed is:

1. A thermoelectric conversion device, comprising:
a thermoelectric element module including a plurality of thermoelectric-element pairs each of which has a P-type thermoelectric element and a N-type thermoelectric element which are electrically connected with each other in series; and
a plurality of heat exchanging members which are electrically joined to the thermoelectric elements and through which heat is transferable between the thermoelectric elements and a heat transfer media, wherein:
the heat exchanging members are arranged at least three rows with respect to a flow direction of the heat transfer media, and respectively joined to the thermoelectric-element pairs; and
an insulating film is provided at a substantially whole surface of an assembly of the thermoelectric element module and the heat exchanging members, by electrodeposition coating.

2. The thermoelectric conversion device according to claim 1, wherein
the insulating film is constructed of a material including an edge-cover resin material.

3. The thermoelectric conversion device according to claim 1, further comprising:
an insulating board; and
a seal member, wherein:
the heat exchanging member has an electrode portion which is connected with the thermoelectric-element pair, and a heat exchanging portion which is directly connected with the electrode portion;
the heat exchanging portions protrude from the insulating board at a protrusion side of the insulating board to be held and are electrically insulated from each other by the insulating board; and
at the protrusion side of the insulating substrate, the seal member is arranged to cover a contact portion between the heat exchanging portions and the insulating board from an outer side of the insulating film.

4. The thermoelectric conversion device according to claim 3, wherein
the seal member covers a substantially whole surface of the insulating board, the surface being at the protrusion side of the heat exchanging portion.

5. The thermoelectric conversion device according to claim 3, wherein
the insulating board constructs a first holding member for holding the heat exchanging portions at a connection side where the heat exchanging portion is connected with the electrode portion.

6. The thermoelectric conversion device according to claim 3, further comprising
a second holding member which is electrically insulating and holds the heat exchanging portions at a side opposite to the connection side where the heat exchanging portion is connected with the electrode portion.

7. The thermoelectric conversion device according to claim 3, further comprising:
a temperature sensor which is arranged at one of a position where the temperature sensor contacts the heat exchanging portions and a position in the vicinity of the hear exchanging portions;
a wiring which is connected with the temperature sensor; and
a wiring insulating film which is electrically insulating and arranged at a substantially whole surface of the wiring by electrodeposition coating.

8. The thermoelectric conversion device according to claim 3, wherein
the plurality of the electrode portions are respectively integrated with the plurality of the heat exchanging portions.

9. A manufacture method for a thermoelectric conversion device including a thermoelectric element module and a plurality of heat exchanging members through which heat is transferable between the thermoelectric element module and a heat transfer media, the thermoelectric element module having a plurality of thermoelectric-element pairs each of which has a P-type thermoelectric element and a N-type thermoelectric element electrically connected with each other in series, the manufacture method comprising:
a joining process for respectively electrically joining the heat exchanging members to the thermoelectric-element pairs, the heat exchanging members being arranged at least three rows with respect to a flow direction of the heat transfer media; and
an immersion process for immersing an assembly of the thermoelectric element module and the heat exchanging members in an immersion sink in which an melted insulating material is provided and applying a predetermined voltage to the assembly so that the insulating material is applied to a substantially whole surface of the assembly, the immersion process being performed after the joining process; and
a baking process for baking the assembly of the thermoelectric element module and the heat exchanging members where the insulating material has been applied in the immersion process so that an insulating film is formed.

10. The manufacture method according to claim 9, wherein
in the immersion process, the insulating material including an edge-cover resin material is used.

11. The manufacture method according to claim 9, wherein
the baking process is performed after the immersion process is repeated several times.

12. The manufacture method according to claim 11, wherein
the immersion process is provided with various immersion conditions for the several times when being performed.

13. The manufacture method according to claim 9, wherein
the baking process is repeated several times, and provided with various baking conditions for the several times.

14. The manufacture method according to claim 9, further comprising
a sealing process for forming a seal member at a protrusion side of the insulating board to cover a contact portion from an outer side of the insulating film, the sealing process being performed after the baking process, wherein:
the heat exchanging member has an electrode portion which is electrically connected with the thermoelectric-element pair and a heat exchanging portion which is directly connected with the electrode portion, the contact portion being between the heat exchanging portions and the insulating board; and
the heat exchanging portions protrude from the insulating board at the protrusion side of the insulating board to be held and are electrically insulated from each other by the insulating board.

15. The manufacture method according to claim 14, wherein
in the sealing process, the seal member is formed to cover a substantially whole surface of the insulating board, the surface being at the protrusion side of the heat exchanging portion.

16. The manufacture method according to claim 14, wherein
in the joining process, the insulating board is arranged as a first holding member to hold the heat exchanging portions at a connection side where the heat exchanging portion is connected with the electrode portion.

17. The manufacture method according to claim 14, wherein
in the joining process, a holding member which is electrically insulating is arranged to hold the heat exchanging portions at a side opposite to a connection side where the heat exchanging portion is connected with the electrode portion.

18. The manufacture method according to claim 14, wherein:
in the joining process, a temperature sensor is arranged at one of a position where the temperature sensor contacts the heat exchanging portions and a position in the vicinity of the hear exchanging portions, and a wiring is connected with the temperature sensor; and
in the immersion process, a wiring insulating film which is electrically insulating is formed at a substantially whole surface of the wiring by applying a voltage to the wiring with the wiring being used as one of a negative pole and a positive pole.

19. The manufacture method according to claim 14, wherein
the plurality of the electrode portions are respectively formed integrally with the plurality of the heat exchanging portions.

20. The manufacture method according to claim 9, wherein
the predetermined voltage is applied to terminals arranged at the thermoelectric element module.

21. The manufacture method according to claim 16, wherein
in the joining process, a second holding member which is electrically insulating is arranged to hold the heat exchanging portions at a side opposite to a connection side where the heat exchanging portion is connected with the electrode portion.
